(19) United States
(12) Patent Application Publication
(10) Pub. No.: US 2004/0193775 A1
(43) Pub. Date: Sep. 30, 2004

(54) Memory pools with moving memory blocks

(76) Inventors: Egidius Gerardus Petrus Van Doren, Eindhoven (NL); Hendrikus Christianus Wilhelmus Van Heesch, Eindhoven (NL)

Correspondence Address: Corporate Patent Counsel, Philips Electronics North America Corporation, PO Box 3001, Briarcliff Manor, NY, 10510, US

(21) Appl. No.: 10/486,450

(22) PCT Filed: Aug. 9, 2002
(86) PCT No.: PCT/IB02/03256

(30) Foreign Application Priority Data
Aug. 15, 2001 (EP) 01203107.6

(51) Int. Cl. G11C 5/00

(52) U.S. Cl. 711/1

(57) ABSTRACT

Method for dynamically allocating/de-allocating memory pools (0, 1, 2, 3) in a physical memory of a computer comprising the steps of: allocating a memory area (4) for said memory pools (0, 1, 2, 3) within said physical memory, allocating said at least one memory block (2a, 2b) within each of said at least one memory pool (0, 1, 2, 3), and writing data in said at least one memory block (2a). To enable dynamic memory allocation, and to reduce memory fragmentation it is proposed that said at least one memory block (2a) is de-allocated after said at least one memory block (2a) is marked empty, and that at least one memory block (2a) is re-allocated within said memory area (4), whereby said memory block (2a) is moved within said memory area (4) during said de-allocation/re-allocation of said at least one memory block (2a, 2b).

The invention relates to a method for dynamically allocating/de-allocating memory pools in a physical memory of a computer comprising the steps of allocating a memory area for said memory pools within said physical memory, allocating at least one memory block within each of said at least one memory pools, and writing data in said at least one memory block. The invention further relates to the use of such a method in digital processing products. The management of computer memory is in particular crucial in digital streaming systems with limited resources.

From EP 0 872 798 A1 a buffer management system for defining and addressing buffers in a buffer zone in a memory of a computer system is known. By use of this system, the size of a plurality of buffer pools is calculated and the buffer pools are allocated. Next, buffer sizes of buffers within said buffer pools are calculated and the buffers are allocated at calculated addresses within said buffer pools, respectively. After the buffers are allocated, data may be written in and read from said buffers. By allocating said pools and said buffers once, fragmentation only occurs if less than one complete memory block is required to store data. The disadvantage of this solution is that the pool and buffer size must be calculated beforehand. It is not possible to increase the pool or buffer sizes after the initial calculation and to exploit the flexibility of programmable hardware, as re-calculating and re-allocating pools and buffers according to current needs is not possible.

As different application modes require different memory pools and not all memory pools can be allocated simultaneously, dynamic allocation/de-allocation has to be carried out.

It is an object of the invention to enable efficient dynamic memory allocation for memory pools. It is a further object of the invention to reduce memory fragmentation.

The object of the invention is solved by a method where said at least one memory block is de-allocated after said at least one memory block is marked empty, and where said at least one memory block is re-allocated within said memory area, whereby said memory block is moved within said memory area during said de-allocation/re-allocation of said at least one memory block.

During allocation/de-allocation of said memory pools or said memory blocks, fragmentation occurs. It is the gist of the invention to reduce this fragmentation by moving said memory pools or said memory blocks within said memory area. By moving said memory blocks, fragmented parts between any two pools or blocks can be removed. As it is important that by moving said memory pools no data gets lost, only empty blocks are moved according to the invention. A block is empty when it is explicitly marked as such. This means that it can be empty even though the data has not been read.

A memory pool with scattered memory blocks according to claim 2 may also be defragmented. In case memory blocks are scattered arbitrarily in said memory area, memory blocks of one memory pool are not allocated at addresses adjacent to each other in said memory area.

While said memory blocks are moved within said memory area, memory fragments between any two of said blocks may be allocated by another memory blocks of any memory pool.

In many cases, memory blocks are allocated according to claim 3.

If memory blocks are de-allocated/re-allocated in the opposite direction according to claim 4, which means that the direction of allocation is opposite to the direction of movement, de-fragmentation speeds up.

Between memory pools, fragmentation may occur. To reduce this fragmentation between two memory pools, a method according to claim 5 is proposed. It is understood that only free memory blocks are moved. Said memory blocks are shifted one after another towards the adjacent memory pool. After all memory blocks of one memory pool are moved towards said adjacent memory pool, no fragmented memory is between these two memory pools. The advantage of said method is that no extra hardware is required, as said memory blocks only undergo allocation/de-allocation without copying of data. Said memory pools are contiguous within said memory area, as they are moved towards each other, which eases memory administration.

While moving said memory blocks through said memory area, these memory blocks may also be clustered according to claim 6. By clustering said memory blocks, the chance of two neighbouring memory blocks being of one same memory pool are increased.

A fragmentation gap between any two memory blocks is preferably allocated for a memory block of the same pool as the block at the next or previous address. This may increases defragmentation speed in the future. The moving direction may be to the left as well as to the right.

As said memory area may only be de-fragmented by moving said memory blocks between allocation/de-allocation of said address range for said memory pools, said memory blocks are allocated/re-allocated according to claim 7.

A cyclical de-allocation/re-allocation according to claim 8 is further preferred. This ensures that defragmentation is carried out on the whole memory area.

The use of an above mentioned method in digital video products, in particular digital television, digital set-top boxes, or in digital streaming applications is another aspect of the invention.

These and other aspects of the invention will be apparent from and elucidated with reference to the embodiments described hereinafter. In the figures show:

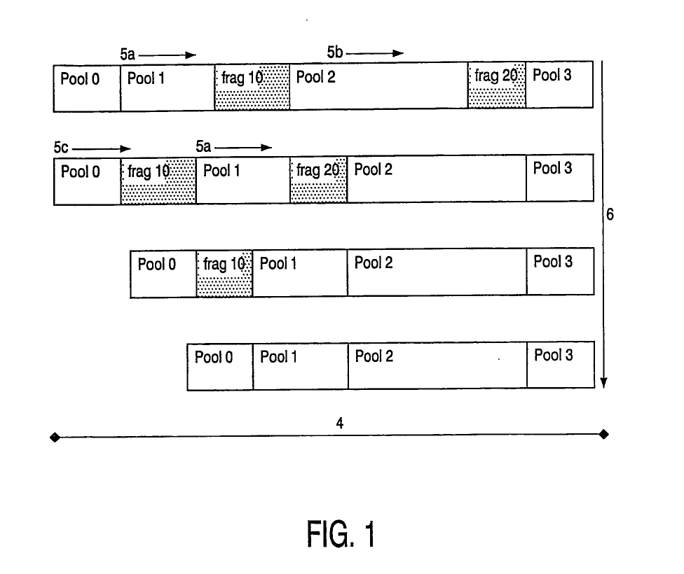

FIG. 1 a memory area with contiguous memory pools;

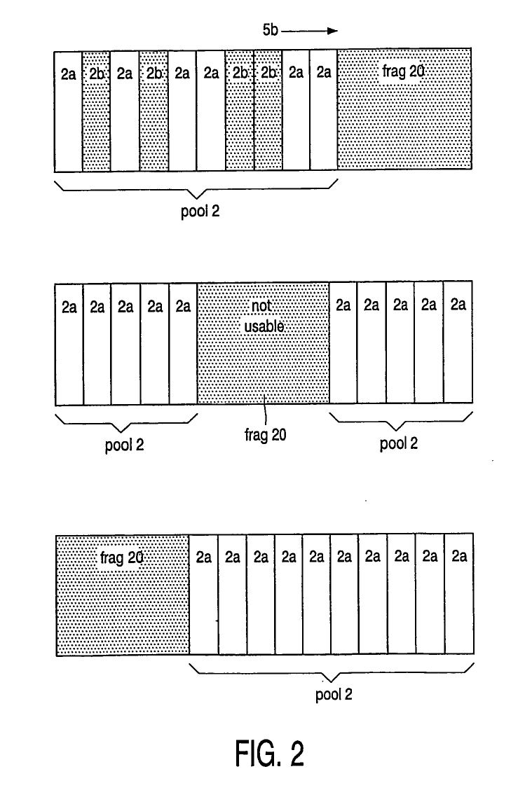

FIG. 2 a memory pool with contiguous memory blocks;

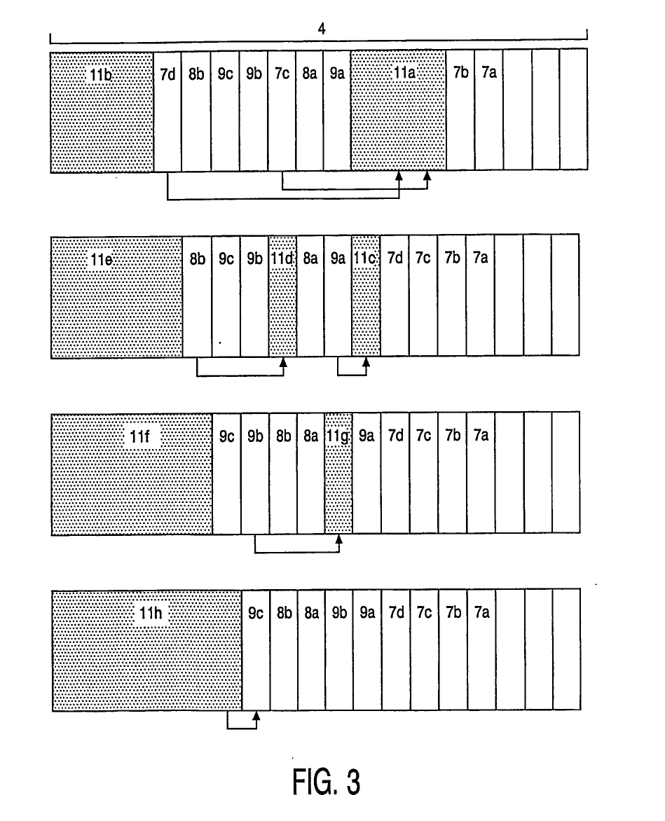

FIG. 3 clustering of memory blocks.

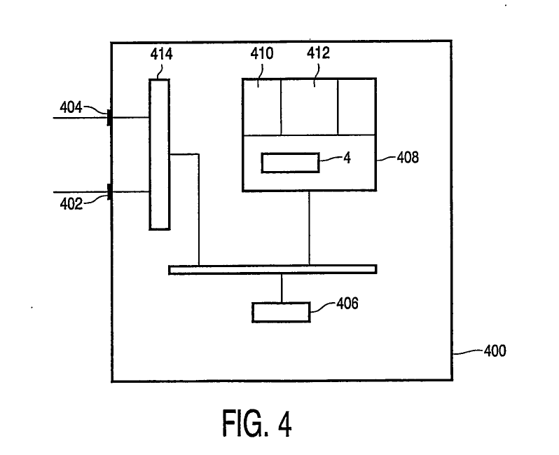

FIG. 4 a digital media data processing apparatus embodying the invention.

In FIG. 1 memory pools 0, 1, 2, and 3 within memory area 4 are depicted. The shown memory pools 0, 1, 2, and 3 are moved within said memory area 4 in direction 5. Time line 6 shows the progress of moving said memory pools 0, 1, 2, and 3. Between said memory pools 2 and 3, memory fragment 20 is located. Memory fragment 10 is located between memory pools 1 and 2.

To defragment said memory area 4, at first said memory pool 2 is shifted towards said memory pool 3 in direction 5b. By moving said memory pool 2 towards memory pool 3, fragment 20 is shifted towards fragment 10. Also pool 1 is moved towards pool 2 in direction 5a and pool 0 is moved towards pool 1 in direction 5c, thus moving memory fragment 10 to the left of said memory pools 0 and 1. When pool 2 is adjacent to pool 3, no memory fragment is between these pools. Memory fragment 20 is between memory pools 1 and 2, and memory fragment 10 is between memory pools 0 and 1.

By moving said memory pools 0, 1, 2, and 3, memory area 4 gets defragmented, as memory fragments 10, 20 are shifted to the left, e.g. to higher memory addresses. These memory fragments may then be again allocated for new memory pools. The shown defragmentation is done without copying data, as only empty memory blocks are moved between de-allocation/re-allocation of memory. The methods of de-allocation/reallocation of memory blocks is depicted in FIG. 2.

FIG. 2 depicts memory pool 2 with empty memory blocks 2b and full, e.g. data containing, memory blocks 2a. When moving said memory pool 2 in direction 5b, all memory blocks 2a have to be de-allocated/re-allocated.

The block size stays constant, only the memory address of each block will change. Memory blocks 2a are shifted from left to right towards memory fragment 20. While shifting said memory blocks 2a, memory within memory fragment 20 gets allocated and occupied by said memory blocks 2a.

Moving said memory blocks 2a is not done by copying said memory blocks 2a. Instead, each memory block 2a can only be moved after its data has been read and said memory block 2a may be de-allocated. After de-allocation of said memory block 2a, a new memory address is allocated at the lowest memory address possible. During movement of memory pool 2, memory fragment 20 moves through said memory pool 2 and memory of this memory fragment cannot be allocated for memory blocks of other memory pools. Memory of said memory fragment 20 is only accessible after said whole memory pool 2 has been moved towards memory pool 3.

As depicted in FIG. 2, memory pool 2 comprises only contiguous memory blocks, which means that memory pool 2 occupies a contiguous address range within a physical memory of a computer system. But it is also possible that memory pools comprise scattered memory blocks, which are not allocated at neighbouring memory addresses. In such a case, memory movement is slightly different. As with contiguous memory pools, a memory fragment cannot be accessed during movement of a memory pool, temporarily less memory is available. With scattered memory pools, memory fragments are still available for allocation, even when the memory fragment is travelling through a memory pool. The memory fragment does not have to be added to the amount of memory occupied by the particular memory pool, and no extra memory is required.

When memory blocks of different pools are intermixed, the speed of defragmentation may be reduced. The defragmentation speed is increased when two neighbouring memory blocks are of the same pool and de-allocated/re-allocated from right to left. The chance of two neighbouring memory blocks being from the same pool can be be increased by Clustering as shown in FIG. 3.

FIG. 3 depicts a memory area 4, occupied with memory blocks 7, 8, and 9 of different memory pools. Between these memory blocks 7, 8, and 9, free memory fragments 11 occur. The depicted clustering works as follows:

Defragmentation is carried out from right to left, e.g. from low memory addresses to high memory addresses. To fill memory fragment 11a, memory blocks of the same memory pool as the memory block to the right of said memory fragment 11a, in this case memory blocks of memory pool 7, are searched. In case the memory blocks 7c, d are free of data and may be de-allocated, these blocks are de-allocated and re-allocated in memory fragment 11a as depicted. If memory blocks 7c, d, are deallocated then the size and position of memory fragments 11a, 11b is changed to memory fragments 11c, 11d, and 11e. Memory block 11c should again be filled with memory blocks of memory pool 7. As there are no memory blocks of memory pool 7 at higher memory addresses left, the next memory block, in this case memory block 9a is shifted to memory fragment 11c. Memory fragment 11d should be filled with memory blocks of memory pool 8. Thus memory block 8b is de-allocated and re-allocated in memory fragment 11d. In the next step, memory block 9b is re-allocated in memory fragment 11g. Eventually, memory block 9c is shifted to the right.

By defragmenting said memory area 4 in the shown way, only one memory fragment 11h is left, which can be easily occupied by new memory blocks.

By reducing memory fragmentation, available memory can be used to its full extent. In particular in digital processing products, e.g. digital video processing where at run time different processing modes are supported, dynamic memory pool allocation is performed and thus memory fragmentation is caused. The invention reduces this memory fragmentation and allows to fully exploit the flexibility of programmable hardware.

FIG. 4 schematically shows a digital media data processing apparatus according to the invention. This digital media processing apparatus 400 receives digital media data through input 402. This data may be digital content of any kind, e.g. video, audio and a combination of these two. The media data may be received from a cable network, from a satellite receiver, from a DVD player or any other suitable device. The apparatus 400 processes the media data and subsequently outputs data through an output 404. The processed data may be reproduced on a display device and through a speaker system or may be recorded on a tape or a disk, depending on the specific nature of the apparatus 400. Examples of the apparatus 400 are: a digital television for reception and reproduction of television programs, a set-top box for receiving and processing of television programs either for display on a separate display device or for storage, and a digital video recorder for processing and storing of programs.

The apparatus 400 may be implemented according to a known computer architecture. The apparatus 400 has a processor 406 for executing program instructions stored in working memory 408. The working memory 408 is shown as a single memory but may be separated into a number of different memory modules depending on the type of stored program and data. The working memory 408 contains an operating unit 410 with the operating system software and an application unit 412 with the application software. Execution of the application software provides the functionality of the apparatus, like a user interface and the data processing. Furthermore, the apparatus 400 has an interface 414 providing communication between the apparatus and external device. The apparatus 400 has a bus 416 connecting the various components of the apparatus and allowing the exchange of commands and data between the components.

The working memory 408 is also arranged to store data, such as the media data or intermediate results, in a memory area 4. For storing data in the memory, the apparatus has a memory management unit 418 for allocating and maintaining the memory pools as described in connection with FIGS. 1-3. In a specific embodiment, the memory management unit is used for dynamically allocating/de-allocating memory pools, like 0, 1, 2, 3, in the working memory by: allocating the memory area 4 for the memory pools 0, 1, 2, 3 within the working memory, allocating a memory block, like 2a and 2b, within each of the memory pools 0, 1, 2, 3, and writing the data in the memory block 2a. To this end, the memory management unit is arranged: to de-allocate the memory block 2a after the memory block is marked empty, and to re-allocate the memory block within the memory area 4, whereby the memory block is moved within the memory area during the de-allocation/reallocation of the memory block. The memory management unit 418 of the apparatus is 400 is shown in the embodiment of FIG. 4 as a software unit separately stored in the working memory. However, an other implementation is also possible, for example the memory management unit may be a part of the operating system software or may be located in a different memory.

1. Method for dynamically allocating/de-allocating memory pools (0, 1, 2, 3) in a physical memory of a computer comprising the steps of:
allocating a memory area (4) for said memory pools (0, 1, 2, 3) within said physical memory,
allocating said at least one memory block (2a, 2b) within each of said at least one memory pools (0, 1, 2, 3), and
writing data in said at least one memory block (2a), characterised in
that said at least one memory block (2a) is de-allocated after said at least one memory block (2a) is marked empty, and
that said at least one memory block (2a) is re-allocated within said memory area (4),
whereby said memory block (2a) is moved within said memory area (4) during said de-allocation/re-allocation of said at least one memory block (2a, 2b).

2. Method according to claim 1, characterised in that memory blocks (2a, 2b) of each of said memory pools (0, 1, 2, 3) are positioned at scattered addresses within said memory area (4).

3. Method according to claim 1, characterised in that memory blocks (2a, 2b) of each of said memory pools (0, 1, 2, 3) are positioned at contiguous memory addresses within said memory area (4).

4. Method according to claim 3, characterised in that said memory blocks (2a, 2b) are de-allocated with increasing/decreasing memory address, and that said memory blocks (2a, 2b) are re-allocated in reverse order with decreasing/increasing memory address, whereby de-fragmentation speed will increase.

5. Method according to claim 3, characterised in that one of said pools (0, 1, 2, 3) is shifted towards another of said pools (0, 1, 2, 3) in said memory area (4) by deallocating/re-allocating said memory blocks (2a, 2b), whereby memory fragments between said pools (0, 1, 2, 3) are removed.

6. Method according to claim 1, characterised in that said memory blocks (2a, 2b) are clustered, whereby memory blocks (2a, 2b) of a same pool (0, 1, 2, 3) are preferably re-allocated at addresses next to each other within said memory area (4).

7. Method according to claim 1, characterised in that said memory blocks (2a, 2b) are de-allocated/re-allocated more often than said pools (0, 1, 2, 3) are de-allocated/reallocated in said memory area (4).

8. Method according to claim 1, characterised in that said de-allocation/reallocation of said memory blocks (2a, 2b) is carried out substantially cyclically, whereby deallocation/re-allocation of every allocated memory block (2a, 2b) is carried out in finite time.

9. Use of a method according to claim 1 in digital processing products, in particular digital television, digital set-top boxes, or in digital streaming applications.

10. Digital media data processing apparatus (400) comprising:
a physical memory (408) for storing the data,
a processor (406) for processing the stored data, and
a memory management unit (418) for dynamically allocating/de-allocating at least one memory pool (0, 1, 2, 3) in the physical memory by:
allocating a memory area (4) for said at least one memory pool (0, 1, 2, 3) within said physical memory,
allocating at least one memory block (2a, 2b) within each of said at least one memory pools (0, 1, 2, 3), and
writing the data in said at least one memory block (2a), characterised in that the memory unit is arranged:
to de-allocate said at least one memory block (2a) after said at least one memory block (2a) is marked empty, and
to re-allocate said at least one memory block (2a) within said memory area (4), whereby said memory block (2a) is moved within said memory area (4) during said de-allocation/re-allocation of said at least one memory block (2a, 2b).
